(19) United States
(12) Patent Application Publication
(10) Pub. No.: US 2026/0107661 A1
(43) Pub. Date: Apr. 16, 2026

(54) COMPOSITE ANODE, PREPARATION METHOD OF COMPOSITE ANODE, DISPLAY PANEL AND DISPLAY DEVICE

(71) Applicant: HKC CORPORATION LIMITED, Shenzhen (CN)

(72) Inventors: Yao Li, Shenzhen (CN); Pei Xu, Shenzhen (CN)

(21) Appl. No.: 19/343,021

(22) Filed: Sep. 29, 2025

(30) Foreign Application Priority Data
Oct. 10, 2024 (CN) 202411405484.8

(51) Int. Cl. H10K 59/80; H10K 59/12

(52) U.S. Cl. CPC H10K 59/80517; H10K 59/1201; H10K 59/80518; H10K 59/878

(57) ABSTRACT

An embodiment of the present application provides a composite anode, a preparation method of a composite anode, a display panel and a display device. The composite anode includes: a first conductive layer; a total reflection layer arranged on a side of the first conductive layer; a composite material layer arranged on a side of the total reflection layer away from the first conductive layer, an edge of the composite material layer being connected to the first conductive layer; and a second conductive layer arranged on a side of the composite material layer away from the first conductive layer, an edge of the second conductive layer being connected to the first conductive layer; the composite material layer includes an indium tin oxide and a carbon nanotube.

### CROSS REFRENCE TO RELATED APPLICATIONS

Pursuant to 35 U.S.C. § 119 and the Paris Convention Treaty, the present application claims the benefit of Chinese Patent Application No. 202411405484.8 filed October 10, 2024, the contents of which are incorporated herein by reference.

### TECHNICAL FIELD

The present application relates to the technical field of display technology, and more particularly to a composite anode, a preparation method of a composite anode, a display panel and a display device.

### BACKGROUND

Organic light-Emitting diode (OLED) display, also known as organic laser display, organic electroluminescence display (OLED). OLED is a current-type organic light-emitting device, which is a phenomenon of luminescence caused by the injection and recombination of carriers, and the luminescence intensity is proportional to the injected current. Under the action of the electric field, the holes generated by the anode and the electrons generated by the cathode of the OLED will move, and are injected into the hole transport layer and the electron transport layer respectively, and migrate to the light-emitting layer. When the holes and the electrons meet in the light-emitting layer, energy excitons are generated, thereby exciting the light-emitting molecules to finally produce visible light.

At present, the commonly used material for the anode is a three-layer sandwich structure of ITO-Ag-ITO (Indium Tin Oxide). Since Ag is an active metal and is easily oxidized or corroded, when patterning is required, the silver layer cannot have any exposed parts, and the ITO layer can fully surround the silver layer. At present, the etching rate is often controlled to achieve the wrapping of the silver layer by the ITO layer, but the wrapping film layer structure formed by this scheme is unstable and uncontrollable, which greatly affects the stability of the anode.

In summary, the existing anode has the problem of unstable wrapping structure of the ITO layer for the silver layer.

### SUMMARY

In view of this, the embodiments of the present application provide a composite anode, a preparation method of a composite anode, a display panel, and a display device to solve the technical problem that the existing anode has an unstable wrapping structure of the ITO layer for the silver layer.

In the first aspect, the present application provides a composite anode, including:

a first conductive layer;

a total reflection layer, arranged on a side of the first conductive layer;

a composite material layer, arranged on a side of the total reflection layer away from the first conductive layer, an edge of the composite material layer being connected to the first conductive layer; and

a second conductive layer, arranged on a side of the composite material layer away from the first conductive layer, an edge of the second conductive layer being connected to the first conductive layer;

the composite material layer includes an indium tin oxide and a carbon nanotube.

In some embodiments, the composite material layer covers the total reflection layer, and the edge of the composite material layer covers a side wall of the total reflection layer and is connected to the first conductive layer;

and/or, the second conductive layer covers the composite material layer, and the edge of the second conductive layer covers a side wall of the composite material layer and is connected to the first conductive layer.

In some embodiments, the composite material layer is prepared from mesh carbon nanotubes and indium tin oxide nanoparticles.

In some embodiments, the first conductive layer and the second conductive layer are light-transmitting conductive oxide layers, and the light-transmitting conductive oxide layers include at least one selected from a group of an indium tin oxide, an indium zinc oxide, an aluminum-doped zinc oxide, a gallium-doped zinc oxide, a zinc oxide, and a tin oxide; and/or, the total reflection layer is a silver layer.

In a second aspect, an embodiment of the present application provides a preparation method of a composite anode, which includes following steps:

providing a light-transmitting conductive oxide and a composite material;

depositing the light-transmitting conductive oxide to form a first conductive layer;

depositing a metal on a side of the first conductive layer to form a total reflection layer;

arranging the composite material on a side of the total reflection layer away from the first conductive layer to form a composite material layer; and depositing the light-transmitting conductive oxide on a side of the composite material layer away from the first conductive layer to form a second conductive layer.

In some embodiments, the composite material is made of mesh carbon nanotubes and indium tin oxide nanoparticles by a high-temperature sintering or a hydrothermal manner.

In some embodiments, the step of arranging the composite material on the side of the total reflection layer away from the first conductive layer to form the composite material layer includes:

patterning the composite material on the side of the total reflection layer away from the first conductive layer by inkjet printing to form the composite material layer; or

first plating the composite material on the side of the total reflection layer away from the first conductive layer, and then exposing, developing, and etching to pattern and form the composite material layer.

In some embodiments, the composite material layer is uniformly covered on an exposed peripheral side of the total reflection layer, and the second conductive layer is uniformly covered on an exposed peripheral side of the composite material layer; or

the composite material layer and the second conductive layer are uniformly covered on an exposed peripheral side of the total reflection layer.

In the third aspect, the embodiment of the present application provides a display panel, which includes:

a substrate;

an insulating layer, arranged on one side of the substrate;

the composite anode according to the first aspect or the composite anode prepared by the preparation method according to the second aspect, the composite anode is arranged on one side of the substrate and on the same side as the insulating layer, the composite anode is partially embedded in the insulating layer, and the two ends of the composite anode are located on the side of the insulating layer away from the substrate;

a light-emitting layer, arranged on the side of the composite anode away from the substrate; and

a cathode, arranged on the side of the light-emitting layer away from the substrate.

In the fourth aspect, the embodiment of the present application provides a display device, such as the display panel and housing as described in the third aspect, the display panel is arranged in the housing.

The composite anode provided in the embodiment of the present application is made of a mesh carbon nanotube/ITO (CNT/ITO) composite nanomaterial by compounding carbon nanotubes with the indium tin oxide. The composition of the anode structure is ITO-CNT/ITO-Ag-ITO. Since the structure of the mesh composite material is more stable, the exposed peripheral side of the total reflection layer is evenly covered and wrapped by the composite material layer and the second conductive layer, thereby preventing the total reflection layer from leaking out and being oxidized and failing, thus the purpose of improving the stability of the anode is achieved.

Compared with the existing anode structure, the preparation method of the composite anode provided in the embodiment of the present application covers a layer of composite material layer on the total reflection layer. Since the structure of the mesh composite material is more stable, during the patterning process, when the total reflection layer shrinks inside the sandwich, the upper composite material layer will be evenly covered along the shrinking surface, while avoiding the fracture at the collapse of the second conductive layer above. The second conductive layer at the top will be slowly deformed and covered under the support of the composite material layer, thereby ensuring that the composite material layer and the second conductive layer cover the exposed peripheral side of the total reflection layer stably and evenly, thus the stability of the anode is improved.

The display panel and the display device provided in the embodiment of the present application have all the above beneficial effects since the display panel and the display device include the above-mentioned composite anode, and because of the high stability of the composite anode, the service life of the display panel and the display device, as well as the brand reputation are significantly improved.

### BRIEF DESCRIPTION OF THE DRAWINGS

In order to explain the embodiments of the present application more clearly, a brief introduction regarding the accompanying drawings that need to be used for describing the embodiments of the present application or the prior art is given below; it is obvious that the accompanying drawings described as follows are only some embodiments of the present application, for those skilled in the art, other drawings can also be obtained according to the current drawings on the premise of paying no creative labor.

FIG. 1 is a schematic diagram of an anode structure in the prior art;

FIG. 2 is a schematic diagram of a process of forming an anode structure in the prior art;

FIG. 3 is a structural schematic diagram of a composite anode provided in an embodiment of the present application;

FIG. 4 is a schematic diagram of a process of forming a structure of a composite anode provided in an embodiment of the present application;

FIG. 5 is a schematic diagram of a microstructure of carbon nanotubes in a composite anode provided in an embodiment of the present application;

FIG. 6 is a schematic diagram of a microstructure of a composite material in a composite anode provided in an embodiment of the present application; and

FIG. 7 is a structural schematic diagram of a display panel provided in an embodiment of the present application.

The reference numerals are listed as following:

10-composite anode; 11-first conductive layer; 12-total reflection layer; 13-composite material layer; 14-second conductive layer.

20-substrate.

30-insulating layer.

40-light-emitting layer; and

50-cathode.

### DESCRIPTION OF THE EMBODIMENTS

In the following description, specific details such as specific system structure, technology, etc. are presented for illustration rather than qualification in order to fully understand the embodiments of the present application. However, it should be clear to those skilled in the art that the present application may also be realized in other embodiments without these specific details. In other cases, detailed descriptions of well-known systems, devices, circuits and methods are omitted so as not to prejudice the description of the present application with unnecessary details.

It should also be understood that the term "and/or" used in the description of the embodiments of the present application and the attached claims refers to any combination of one or more of the associated listed items and all possible combinations, including these combinations.

It is noted that when a component is referred to as being “fixed to” or “disposed on” another component, it can be directly or indirectly on another component. When a component is referred to as being “connected to” another component, it can be directly or indirectly connected to another component.

In the description of the present application, it needs to be understood that, directions or location relationships indicated by terms such as “length”, “width”, “up”, “down”, “front”, “rear”, “left”, “right”, “vertical”, “horizontal”, “top”, “bottom”, “inside”, “outside”, and so on are the directions or location relationships shown in the accompanying figures, which are only intended to describe the present application conveniently and simplify the description, but not to indicate or imply that an indicated device or component must have specific locations or be constructed and manipulated according to specific locations; therefore, these terms shouldn’t be considered as any limitation to the present application.

In addition, the terms "first", "second", "third", etc. in the description of the present application and the accompanying claims are used only to distinguish the description and are not to be construed as indicating or implying relative importance.

References to "one embodiment" or "some embodiments", etc. as described in the description of the present application means that specific features, structures, or features described in conjunction with the embodiments are included in one or more embodiments of the present application. Thus, the terms "in one embodiment", "in some embodiments", "in some other embodiments", "in some further embodiments", etc., which appear in differences in the specification, do not necessarily all refer to the same embodiments, but mean "one or more but not all embodiments" unless otherwise specifically emphasized. The terms "including", "containing", "having" and their variations all mean "including but not limited to" unless otherwise specifically emphasized. The terms "include", "contain", "possess" and their variations all imply "include but are not limited to", unless otherwise specifically emphasized. "Multiple" refers to two or more.

The OLED, namely Organic Light-Emitting Diode (OLED);

ITO, namely Indium Tin Oxide (ITO);

Ag, namely Silver;

CNT, namely Carbon Nanotubes (CNT or CNTs);

CNT/ITO, namely Carbon Nanotube/Indium Tin Oxide composite material.

The OLED device is composed of a substrate, a cathode, an anode, a hole injection layer, an electron injection layer, a hole transport layer, an electron transport layer, an electron blocking layer, a hole blocking layer, and a light-emitting layer, etc. Among them, the substrate is the basis of the entire device, and all functional layers need to be evaporated onto the substrate of the device; the glass is usually used as the substrate of the device, but if a bendable flexible OLED device needs to be made, other materials such as plastics need to be used as the substrate of the OLED device.

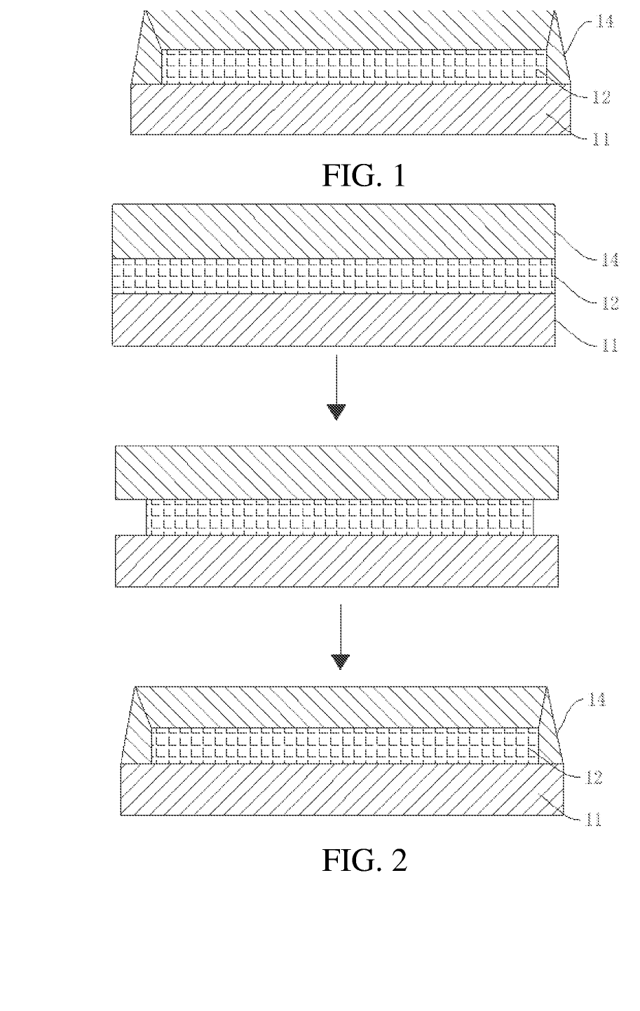

The anode is connected to the positive pole of the external driving voltage of the device. The holes in the anode are moved to the light-emitting layer in the device under the drive of the external driving voltage, the work function of the anode is required to be as high as possible to improve the hole injection efficiency. The OLED device requires that one side of the electrode must be light-transmitting. Taking the top-emitting OLED as an example, the anode is located below the light-emitting layer. The light emitted by the light-emitting layer are emitted to the surrounding side. The light below needs to be reflected by the anode, so a total reflection layer is required. The upper layer requires a light-transmitting electrode. Therefore, the anode usually uses a light-transmitting material ITO with a high work function. The ITO has a transmittance of more than 80% in the wavelength range of 400nm to 1000nm, and also has a high transmittance in the near-ultraviolet region. The silver layer needs to be protected by other relatively inert electrodes. The common lower layer uses an ITO layer. The anode structure in the prior art is shown in FIGS. 1 and 2.

In general process preparation, the three-layer structure of the anode includes a first conductive layer 11, a total reflection layer 12, and a second conductive layer 14. A method of sequential coating and one-time etching is adopted, that is, as shown in FIG. 2, after the three layers are sequentially coated and the exposure and development process are completed, during the etching process, the etching rate of the second conductive layer 14 and the total reflection layer 12 by the etching liquid is generally controlled so that the etching rate of the total reflection layer 12 is greater than that of the second conductive layer 14. At this time, the total reflection layer 12 will shrink. After the shrinkage reaches a certain degree, the second conductive layer 14 above will break without the support of the total reflection layer 12. At this time, the second conductive layer 14 above will fall on the exposed surface of the total reflection layer 12 after the film is broken and accumulate, thereby covering the exposed surface of the total reflection layer 12, thereby protecting the total reflection layer 12. In this way, the film fracture of the second conductive layer 14 is a brittle fracture of the film. Due to the high brittleness of the ITO layer itself, large pores and cracks will be generated at the fracture, and the film layer below is unevenly stacked, the film layer continuity of the wrapping surface is poor, and the wrapping of the total reflection layer 12 is also poor. Therefore, under this process, the film thickness around the total reflection layer 12 will be uneven and the film quality will be poor, which has a great impact on the stability of the anode.

After research, it was found that the structure of carbon nanotubes is the same as the lamellar structure of graphite and has good conductivity. The resistance of carbon nanotubes has nothing to do with their length and diameter. When electrons pass through the carbon nanotubes, they will not generate heat to heat the carbon nanotubes. The transmission of electrons in the carbon nanotubes is like the transmission of light signals in optical fiber cables, with little energy loss, so it has high conductivity.

Therefore, the embodiment of the present application prepares a composite material with a mesh structure by compounding the carbon nanotubes and the indium tin oxide. The material has high conductivity. Since the work function of the carbon nanotubes is about 4.95 eV (electron volts) and the work function of the ITO is about 5 eV (electron volts), the work function of the composite material meets the requirements of the anode. The composite material layer 13 formed by the composite material cooperates with the second conductive layer 14 to uniformly cover and wrap the total reflection layer 12 to avoid the peripheral side of the total reflection layer 12 being exposed to the external environment, thereby effectively preventing the total reflection layer 12 from being oxidized and thus failing, and the stability of the anode is greatly improved.

It should be noted that the thickness direction of the composite anode 10 and the display panel mentioned in the embodiment of the present application is the Y direction in the figure, and the X direction is the length/width direction of the composite anode 10 and the display panel. The above is only for the convenience of understanding the technical solution of the embodiment of the present application, and should not be understood as limiting the scope of the embodiment of the present application.

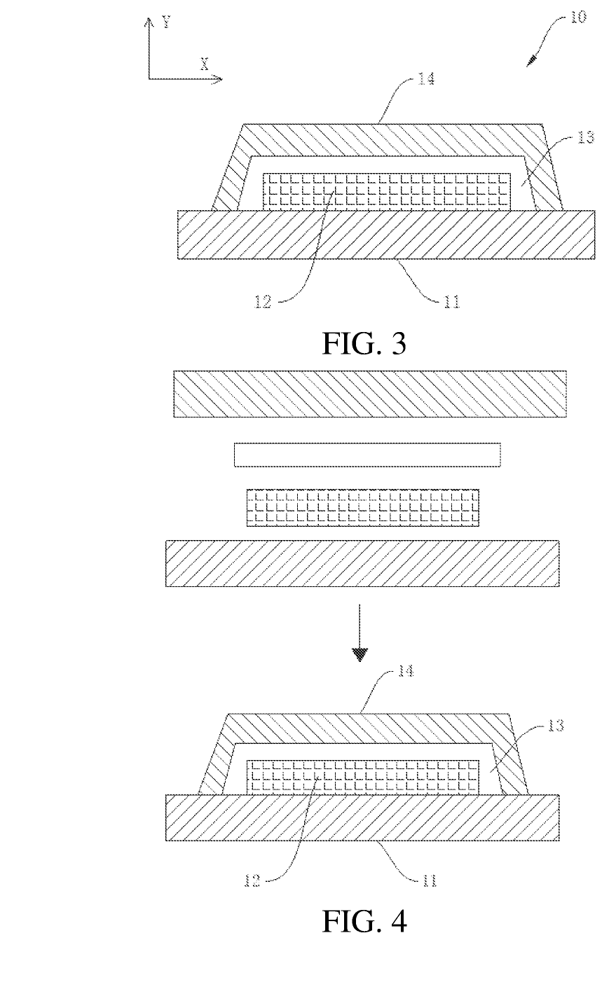

The first aspect of the embodiment of the present application provides a composite anode 10, as shown in FIGS. 3 to 6, the composite anode 10 includes a first conductive layer 11, a total reflection layer 12, a composite material layer 13, and a second conductive layer 14.

The total reflection layer 12 is arranged on a side of the first conductive layer 11.

The composite material layer 13 is arranged on the side of the total reflection layer 12 away from the first conductive layer 11, and the edge of the composite material layer 13 is connected to the first conductive layer 11.

The second conductive layer 14 is arranged on the side of the composite material layer 13 away from the first conductive layer 11, and the edge of the second conductive layer 14 is connected to the first conductive layer 11.

The composite material layer 13 includes the indium tin oxide and the carbon nanotubes.

The composite anode 10 provided in the embodiment of the present application obtains a mesh composite material by compounding the carbon nanotubes and the ITO, so that a composite material layer 13 that uniformly covers and wraps the total reflection layer 12 can be formed on the total reflection layer 12, thereby improving the stability of the anode. Moreover, since the composite material has high conductivity, high mechanical strength, good light transmittance and low cost, it is conducive to commercial production.

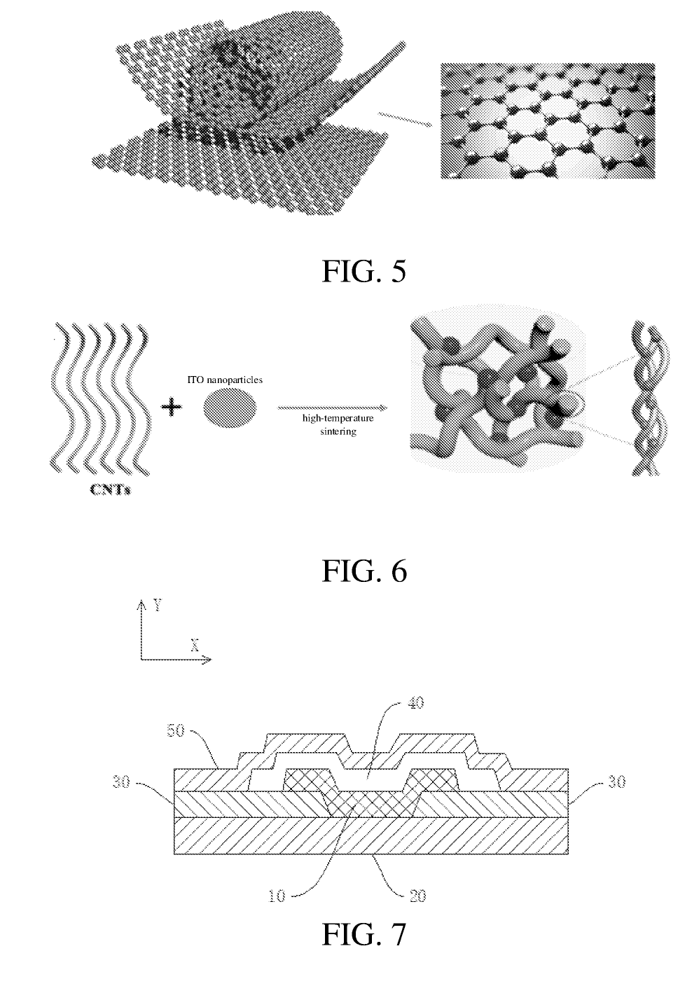

In some embodiments, as shown in FIGS. 5 and 6, the composite material layer 13 is prepared from a mesh carbon nanotube and indium tin oxide nanoparticles. The structure of the carbon nanotube is the same as the lamellar structure of graphite and has good electrical conductivity. The resistance of carbon nanotubes has nothing to do with their length and diameter. When electrons pass through the carbon nanotubes, they will not generate heat to heat the carbon nanotubes. The transmission of electrons in the carbon nanotubes is like the transmission of light signals in optical fiber cables, with little energy loss, so it has high conductivity. In the application, as shown in FIG. 6, the ITO nanoparticles and CNT are subjected to high-temperature sintering or hydrothermal manner so that the ITO nanoparticles can be attached to the gaps of the CNTs, the mechanical strength and electrical conductivity of the composite material are effectively enhanced

In the embodiment, the high electrical conductivity of CNTs can significantly improve the electrical conductivity of the overall material. The high strength of CNTs can increase the tensile strength and toughness of the composite material. The light transmittance of the ITO nanoparticles allows the composite material to still maintain a high light transmittance. Compared with pure ITO, the use of CNTs can reduce costs because ITO is more expensive.

In some embodiments, as shown in FIGS. 3 and 4, the composite material layer 13 is covered on the total reflection layer 12, and the edge of the composite material layer 13 covers the side wall of the total reflection layer 12 and is connected to the first conductive layer 11. In other words, the end of the composite material layer 13 along the length or width direction of the composite anode 10 is located on the first conductive layer 11 and is connected to the first conductive layer 11, that is, the composite material layer 13 and the first conductive layer 11 together cover and encapsulate the total reflection layer 12 to prevent the peripheral side of the total reflection layer 12 from being exposed to the external environment, thereby effectively preventing the active metal in the total reflection layer 12 from being oxidized, and ultimately achieving the purpose of improving the stability of the anode.

In some embodiments, as shown in FIGS. 3 and 4, the second conductive layer 14 covers the composite material layer 13, and the edge of the second conductive layer 14 covers the side wall of the composite material layer 13 and is connected to the first conductive layer 11. In other words, the end of the second conductive layer 14 along the length or width direction of the composite anode 10 is located on the first conductive layer 11 and is connected to the first conductive layer 11. The second conductive layer 14 cooperates with the first conductive layer 11 to uniformly cover and wrap the composite material layer 13 and the total reflection layer 12. On the basis of the composite material layer 13, the sealing of the covering and wrapping is further improved, thereby further protecting the total reflection layer 12, and achieving the effect of fully improving the stability of the anode.

In other embodiments, other functional layers can be arranged between the first conductive layer 11 and the total reflection layer 12, between the total reflection layer 12 and the composite material layer 13, and between the composite material layer 13 and the second conductive layer 14, which are not limited in the embodiments of the present application.

In some embodiments, the first conductive layer 11 and the second conductive layer 14 are light-transmitting conductive oxide layers, and the light-transmitting conductive oxide layers include at least one selected from a group of an indium tin oxide, an indium zinc oxide, an aluminum-doped zinc oxide, a gallium-doped zinc oxide, a zinc oxide, and a tin oxide. In some embodiments, the first conductive layer 11 is an indium tin oxide layer, and the second conductive layer 14 is also an indium tin oxide layer. The ITO has good optical transmittance, allowing light to pass through, which is essential for displays that need to view images from the front. In OLED display technology, the ITO is often used as an anode material because its low work function helps holes to be injected from the anode into the organic layer.

In some embodiments, the total reflection layer 12 is a silver layer. In some embodiments, in an OLED display panel, the anode is usually required to have two main characteristics: light transmittance and good conductivity. In the embodiment of the present application, the anode includes a total reflection layer 12 to optimize the light extraction efficiency. The benefits of using silver (Ag) as the total reflection layer 12 are mainly reflected in the following aspects:

High reflectivity: The silver has a very high reflectivity, especially in the visible spectrum, which allows it to effectively reflect unextracted light back to the light-emitting layer 40. By reflecting the light that is not extracted, the chance of light being emitted can be increased, thereby improving the overall brightness and efficiency of the display panel.

High conductivity: The silver is a metal with extremely high conductivity, which means that it can efficiently transmit current. The presence of the silver layer can reduce the resistance of the entire anode, reduce energy loss, and thus improve the efficiency of the OLED.

Total reflection effect: By introducing the total reflection layer 12 in the anode, the propagation path of light inside the OLED can be changed, and the loss caused by multiple reflections of light between the substrate 20 and other layers can be reduced. The total reflection layer 12 helps to direct more light to the emission direction, thereby improving the light extraction efficiency.

Low absorption: The silver has lower light absorption characteristics relative to other metals. This reduces the possibility of light being absorbed when passing through the anode, thus the amount of light extracted is further increased.

Color purity: The high reflectivity of silver helps maintain the purity of color because dispersion and absorption are reduced during light transmission. This is very important for display technology that pursues high color accuracy and contrast.

Chemical stability: The silver has good chemical stability, which helps to extend the service life of OLED display panels.

Layer thickness adjustment: The thickness of the silver layer can be adjusted according to specific design requirements to optimize the balance between reflectivity and conductivity.

The embodiment of the present application also provides a preparation method of a composite anode 10, the preparation method includes the following steps:

In a step S10, a light-transmitting conductive oxide and a composite material are provided;

In a step S20, a light-transmitting conductive oxide is deposited to form a first conductive layer 11;

In a step S30, a metal is deposited on one side of the first conductive layer 11 to form a total reflection layer 12;

In a step S40, a composite material is arranged on the side of the total reflection layer 12 away from the first conductive layer 11 to form a composite material layer 13;

In a step S50, a light-transmitting conductive oxide is deposited on the side of the composite material layer 13 away from the first conductive layer 11 to form a second conductive layer 14.

Compared with the existing anode structure, the preparation method of the composite anode 10 provided in the embodiment of the present application covers a layer of composite material layer 13 on the total reflection layer 12. Since the structure of the mesh composite material is more stable, during the patterning process, when the total reflection layer 12 shrinks inside the sandwich, the composite material layer 13 at an upper layer will be evenly covered along the shrinking surface, while avoiding the fracture at the collapse of the second conductive layer 14 above. The second conductive layer 14 at a topmost layer will be slowly deformed and covered under the support of the composite material layer 13, thereby ensuring that the composite material layer 13 and the second conductive layer 14 cover the exposed peripheral side of the total reflection layer 12 stably and evenly, thus the stability of the anode is improved.

In applications, as shown in FIGS. 3 and 4, the materials of the composite anode 10 are ITO (-100 angstroms)-CNT/ITO (-100 angstroms)-Ag (-1000 angstroms)-ITO (-200 angstroms) from top to bottom. The ITO and Ag coating (PVD deposition) are performed from bottom to top respectively. The thickness units of the layer structure are in brackets, and ~ means approximately. The advantages of the composite anode 10 structure include that the resistance of the anode can be significantly reduced and the current transmission efficiency can be improved by introducing CNTs and silver layers. The silver layer, as a total reflection layer 12, can redirect the unextracted light back to the light-emitting layer 40, thus the probability of light emission is increased, the propagation path of light is optimized and the multiple reflection losses of light inside the OLED is reduced. Although the silver layer is thick, the overall optical transmittance can be maintained by designing a multi-layer structure, especially the CNT/ITO layer and the upper and lower ITO layers. The mechanical stability is improved since that the CNT/ITO layer and the lower ITO layer provide additional mechanical protection, and the risk of the silver layer breaking due to external stress is reduced. Chemical stability is maintained due that the CNT/ITO layer can reduce the contact of the silver layer with oxygen and moisture in the air to avoid oxidation of the silver layer.

In the step S10, the light-transmitting conductive oxide is the indium tin oxide, and the composite material is made of the mesh carbon nanotubes and the indium tin oxide nanoparticles by a high-temperature sintering or a hydrothermal manner. The composite material synthesized by mesh carbon nanotubes and ITO nanoparticles through a specific preparation method (such as the high temperature sintering or the hydrothermal manner) is usually called CNT/ITO composite material. This material combines the high conductivity and mechanical strength of CNT with the good light transmittance and conductivity of ITO. Among them, the high temperature sintering manner is that CNTs and ITO nanoparticles are mixed and sintered at high temperature to form a strong connection between the two materials. The advantages is that it can improve the conductivity and mechanical stability of the composite material. The hydrothermal is that it is to synthesize composite materials in high pressure and high temperature aqueous solution. This manner is conducive to the formation of a uniformly dispersed composite structure. A more uniform dispersion effect can be obtained while retaining the light transmittance of the material.

In the steps S20 and S30, a transparent conductive oxide is deposited to obtain a first conductive layer 11, that is, the indium tin oxide is deposited. Then a metal is deposited on one side of the first conductive layer 11. In some embodiments, the metal is silver (Ag) to form the total reflection layer 12.

In the step S40, the composite material being arranged on the side of the total reflection layer 12 away from the first conductive layer 11 to form the composite material layer 13 includes:

The composite material is patterned on the side of the total reflection layer 12 away from the first conductive layer 11 by inkjet printing to form the composite material layer 13. Among them, the uppermost layer of second conductive layer 14 is still deposited by PVD, and then patterned by ordinary exposure, development, etching and other photolithography processes. In this scheme, since the CNT properties are relatively stable and the etching is difficult, patterning is used when the film is directly plated, and etching is not performed subsequently. In this way, it can be ensured that the second conductive layer 14 and the composite material layer 13 uniformly cover and wrap the total reflection layer 12.

In other embodiments, the composite material is first plated on the side of the total reflection layer 12 away from the first conductive layer 11, and then exposed, developed, and etched to pattern to form the composite material layer 13. In this way, etching can be performed once, which is conducive to simplifying the process steps. In applications, the composite material needs to be connected to Ag and ITO for etching, so it is necessary to reduce the CNT content and increase the concentration of the etching solution, or use other etching methods, such as plasma bombardment scheme to modify the position to be disconnected, and then use the etching solution for etching. In this way, it can be ensured that when the silver layer is etched, the composite material layer 13 collapses evenly, and no large pores and cracks will be generated, which ensures the coverage and wrapping of the silver layer (total reflection layer 12) and improves its stability.

In some embodiments, the first conductive layer 11 can be made of an inert conductor material other than ITO material, and it only needs to be etched at a speed less than or equal to the second conductive layer 14 under the above-mentioned etching solution. It is recommended to use a rate less than that of ITO, so that the second conductive layer 14 can collapse to the lower layer so that it can be carried out on the bottom plane of Ag. The collapse height of the second conductive layer 14 is equal to the height of the total reflection layer 12, the coverage thickness of the composite material layer 13 and the second conductive layer 14 on the total reflection layer 12 is ensured, and the occurrence of faults between the film layers caused by too high a height is reduced.

In some embodiments, as shown in FIGS. 3 and 4, the composite material layer 13 is evenly covered on the exposed peripheral side of the total reflection layer 12, and the second conductive layer 14 is evenly covered on the exposed peripheral side of the composite material layer 13. The composite material layer 13 is first used to preliminarily cover and wrap the total reflection layer 12, and then the second conductive layer 14 is used to cover and wrap the composite material layer 13, so that the total reflection layer 12 can be protected to the greatest extent to avoid being affected by the external environment, thus the effect of improving the stability of the anode is achieved.

In other embodiments, the composite material layer 13 and the second conductive layer 14 are evenly covered on the exposed peripheral side of the total reflection layer 12. In other words, the exposed peripheral side of the total reflection layer 12 can be covered and wrapped by the combination of the composite material layer 13 and the second conductive layer 14, and it is not limited to fully cover the total reflection layer 12 by one of the composite material layer 13 or the second conductive layer 14.

The embodiment of the present application further provides a display panel, as shown in FIG. 7 , the display panel includes a substrate 20, an insulating layer 30, a composite anode 10, a light-emitting layer 40 and a cathode 50; and the above components are stacked in sequence along the thickness direction of the display pane.

The insulating layer 30 is arranged on one side of the substrate 20.

The composite anode 10 is arranged on one side of the substrate 20, the composite anode 10 and the insulating layer 30 are located on the same side of the substrate 20, the composite anode 10 is partially embedded in the insulating layer 30, and the two ends of the composite anode 10 are located on the side of the insulating layer 30 away from the substrate 20. The composite anode 10 is the composite anode 10 provided in the first aspect or the composite anode 10 prepared by the preparation method described in the second aspect.

The light-emitting layer 40 is arranged on the side of the composite anode 10 away from the substrate 20.

The cathode 50 is arranged on the side of the light-emitting layer 40 away from the substrate 20.

The display panel provided in the embodiment of the present application has all the beneficial effects described in the first and second aspects because the display panel includes the above composite anode 10, that is, the preparation method provided in the second aspect can evenly cover and wrap the mesh composite material on the total reflection layer 12 to prevent the total reflection layer 12 from being exposed to the external environment, and the stability compared with the existing anode is effectively improved.

In applications, the two ends of the composite anode 10 refer to the two ends of the composite anode 10 along the length or width direction of the display panel in FIG. 7. In practical applications, that is, the peripheral side of the composite anode 10 is located on the insulating layer 30. The light-emitting layer 40 and the insulating layer 30 cover and wrap the composite anode 10. Specifically, in the manufacturing process of the display panel, the light-emitting layer 40 is first deposited on the side of the composite anode 10 away from the substrate 20, and then the edge of the light-emitting layer 40 is wrapped and covered by the photolithography technology (spin coating photoresist, exposure, development, etching, peeling). Similarly, the cathode 50 is also designed in the same way to cover and wrap the light-emitting layer 40; thus the structural stability of the display panel is ensured and the display effect is improved.

In applications, the display panel also includes a hole injection layer, an electron injection layer, a hole transport layer, an electron transport layer, an electron blocking layer and a hole blocking layer. The positional relationship of the above layer structures is: the substrate 20, the insulating layer 30, the composite anode 10, the hole injection layer, the hole transport layer, the electron blocking layer, the light-emitting layer 40, the hole blocking layer, the electron transport layer, the electron injection layer, the cathode 50 arranged in sequence. The functions of each layer are as follows:

The function of the substrate 20 is to provide a basic platform to support the entire OLED structure. It is usually glass or plastic film. The function of the insulating layer 30 is to isolate the substrate 20 from the subsequent layers to ensure that the charge passes correctly through the active layer of the OLED instead of the substrate 20. In some embodiments, the insulating layer 30 can also be omitted. The function of the composite anode 10 is to inject holes into the OLED, the composite anode 10 is usually a light-transmitting conductive material, such as ITO (indium tin oxide). In the embodiment of the present application, a mesh material composed of CNT and ITO is used. The function of the hole injection layer is to improve the injection efficiency of holes from the anode to the hole transport layer. The function of the hole transport layer is to transport holes from the hole injection layer to the light-emitting layer 40. The function of the electron blocking layer is to prevent electrons from flowing back from the electron transport layer to the hole transport layer, thereby reducing non-radiative recombination. The function of the light-emitting layer 40 is that holes and electrons recombine in this layer to form excitons, and emit photons when the excitons decay. The function of the hole blocking layer is to prevent holes from entering the electron transport layer, so as to reduce non-radiative recombination. The function of the electron transport layer is to transport electrons from the electron injection layer to the light-emitting layer 40. The function of the electron injection layer is to improve the injection efficiency of electrons from the cathode 50 to the electron transport layer. The function of the cathode 50 is to inject electrons into the OLED, the cathode 50 is usually a metal or alloy, such as aluminum, magnesium or lithium.

The embodiment of the present application also provides a display device, which includes a display panel of the third aspect and a housing (not shown in the figure), and the display panel is arranged in the housing.

The display device provided in the embodiment of the present application has a highly stable composite anode 10, so that the service life of the display device and the brand reputation are significantly improved.

In the above embodiments, the description of each embodiment has its own emphasis. For the part that is not described or recorded in detail in a certain embodiment, refer to the relevant description of other embodiments.

The above-described embodiments are only used to illustrate the technical solutions of the embodiments of the present application, rather than to limit them. Although the embodiments of the present application are described in detail with reference to the aforementioned embodiments, those skilled in the art should understand that they can still modify the technical solutions recorded in the aforementioned embodiments, or make equivalent replacements for some of the technical features therein. These modifications or replacements do not deviate the essence of the corresponding technical solutions from the spirit and scope of the technical solutions of the embodiments of the embodiments of the present application, and should all be included in the protection scope of the embodiments of the present application.

What is claimed is:

1. A composite anode, comprising:
a first conductive layer;
a total reflection layer, arranged on a side of the first conductive layer;
a composite material layer, arranged on a side of the total reflection layer away from the first conductive layer, an edge of the composite material layer being connected to the first conductive layer; and
a second conductive layer, arranged on a side of the composite material layer away from the first conductive layer, an edge of the second conductive layer being connected to the first conductive layer;
wherein the composite material layer comprises an indium tin oxide and a carbon nanotube.

2. The composite anode according to claim 1, wherein the composite material layer covers the total reflection layer, and the edge of the composite material layer covers a side wall of the total reflection layer and is connected to the first conductive layer.

3. The composite anode according to claim 1, wherein the second conductive layer covers the composite material layer, and the edge of the second conductive layer covers a side wall of the composite material layer and is connected to the first conductive layer.

4. The composite anode according to claim 1, wherein the composite material layer covers the total reflection layer, and the edge of the composite material layer covers a side wall of the total reflection layer and is connected to the first conductive layer; and
the second conductive layer covers the composite material layer, and the edge of the second conductive layer covers a side wall of the composite material layer and is connected to the first conductive layer.

5. The composite anode according to claim 1, wherein the composite material layer is prepared from mesh carbon nanotubes and indium tin oxide nanoparticles.

6. The composite anode according to claim 1, wherein the first conductive layer and the second conductive layer are light-transmitting conductive oxide layers, and the light-transmitting conductive oxide layers comprises at least one selected from a group of an indium tin oxide, an indium zinc oxide, an aluminum-doped zinc oxide, a gallium-doped zinc oxide, a zinc oxide, and a tin oxide; and
the total reflection layer is a silver layer.

7. The composite anode according to claim 1, wherein the first conductive layer and the second conductive layer are light-transmitting conductive oxide layers, and the light-transmitting conductive oxide layers comprises at least one selected from a group of an indium tin oxide, an indium zinc oxide, an aluminum-doped zinc oxide, a gallium-doped zinc oxide, a zinc oxide, and a tin oxide; or
the total reflection layer is a silver layer.

8. A preparation method of a composite anode, comprising following steps:
providing a light-transmitting conductive oxide and a composite material;
depositing the light-transmitting conductive oxide to form a first conductive layer;
depositing a metal on a side of the first conductive layer to form a total reflection layer;
arranging the composite material on a side of the total reflection layer away from the first conductive layer to form a composite material layer; and
depositing the light-transmitting conductive oxide on a side of the composite material layer away from the first conductive layer to form a second conductive layer.

9. The preparation method according to claim 8, wherein the composite material is made of mesh carbon nanotubes and indium tin oxide nanoparticles by a high-temperature sintering or a hydrothermal manner.

10. The preparation method according to claim 8, wherein the step of arranging the composite material on the side of the total reflection layer away from the first conductive layer to form the composite material layer comprises:
patterning the composite material on the side of the total reflection layer away from the first conductive layer by inkjet printing to form the composite material layer.

11. The preparation method according to claim 8, wherein the step of arranging the composite material on the side of the total reflection layer away from the first conductive layer to form the composite material layer comprises:
first plating the composite material on the side of the total reflection layer away from the first conductive layer, and then exposing, developing, and etching to pattern and form the composite material layer.

12. The preparation method according to claim 8, wherein the composite material layer is uniformly covered on an exposed peripheral side of the total reflection layer, and the second conductive layer is uniformly covered on an exposed peripheral side of the composite material layer.

13. The preparation method according to claim 8, wherein the composite material layer and the second conductive layer are uniformly covered on an exposed peripheral side of the total reflection layer.

14. A display panel, comprising:
a substrate;
an insulating layer, arranged on a side of the substrate;
a composite anode comprising:
a first conductive layer;
a total reflection layer, arranged on a side of the first conductive layer;
a composite material layer, arranged on a side of the total reflection layer away from the first conductive layer, an edge of the composite material layer being connected to the first conductive layer; and
a second conductive layer, arranged on a side of the composite material layer away from the first conductive layer, an edge of the second conductive layer being connected to the first conductive layer;
wherein the composite material layer comprises an indium tin oxide and a carbon nanotube;
or a composite anode obtained by following steps:
providing a light-transmitting conductive oxide and a composite material;
depositing the light-transmitting conductive oxide to form a first conductive layer;
depositing a metal on a side of the first conductive layer to form a total reflection layer;
arranging the composite material on a side of the total reflection layer away from the first conductive layer to form a composite material layer; and
depositing the light-transmitting conductive oxide on a side of the composite material layer away from the first conductive layer to form a second conductive layer;
wherein the composite anode is arranged on a side of the substrate and is located on a same side as the insulating layer, the composite anode is partially embedded in the insulating layer, and both ends of the composite anode are located on a side of the insulating layer away from the substrate;
a light-emitting layer, arranged on a side of the composite anode away from the substrate; and
a cathode, arranged on a side of the light-emitting layer away from the substrate.

15. The display panel according to claim 14, wherein the composite material layer covers the total reflection layer, and the edge of the composite material layer covers a side wall of the total reflection layer and is connected to the first conductive layer.

16. The display panel according to claim 14, wherein the second conductive layer covers the composite material layer, and the edge of the second conductive layer covers a side wall of the composite material layer and is connected to the first conductive layer.

17. The display panel according to claim 14, wherein the composite material layer covers the total reflection layer, and the edge of the composite material layer covers a side wall of the total reflection layer and is connected to the first conductive layer; and
the second conductive layer covers the composite material layer, and the edge of the second conductive layer covers a side wall of the composite material layer and is connected to the first conductive layer.

18. The display panel according to claim 14, wherein the composite material layer is prepared from mesh carbon nanotubes and indium tin oxide nanoparticles.

19. The display panel according to claim 14, wherein the first conductive layer and the second conductive layer are light-transmitting conductive oxide layers, and the light-transmitting conductive oxide layers comprises at least one selected from a group of an indium tin oxide, an indium zinc oxide, an aluminum-doped zinc oxide, a gallium-doped zinc oxide, a zinc oxide, and a tin oxide;
and/or the total reflection layer is a silver layer.
